(19) United States
(12) Patent Application Publication
(10) Pub. No.: US 2026/0074657 A1
(43) Pub. Date: Mar. 12, 2026

(54) SEMICONDUCTOR CIRCUIT FOR REDUCING OUTPUT DISTORTION

(71) Applicant: Sound Semiconductor, Inc., Sonora, CA (US)

(72) Inventor: Derek F. BOWERS, Los Altos Hills, CA (US)

(21) Appl. No.: 18/882,663

(22) Filed: Sep. 11, 2024

(51) Int. Cl. H03F 1/32; H03F 1/22; H03F 3/45

(52) U.S. Cl. CPC H03F 1/3211; H03F 1/22; H03F 3/45085; H03F 3/45174; H03F 3/45484; H03F 2200/03

(57) ABSTRACT

The disclosed semiconductor amplifier circuit addresses distortion reduction in audio signal amplification by incorporating semiconductor devices with substrate loss pickup elements. The circuit includes a differential amplifier setup using semiconductor devices for initial signal processing and a cascode stage with semiconductor devices equipped with substrate loss pickup elements for mitigating substrate loss currents. Bias networks set operating points for linear amplification, complemented by a power supply connection for operational voltage. Substrate loss pickup elements are configured to reduce distortion by capturing uncollected charge carriers, enhancing audio fidelity.

### BACKGROUND

In semiconductor amplifier circuits, particularly those utilizing bipolar junction transistors (BJTs), distortion and substrate loss currents are significant challenges that impact audio signal fidelity. Distortion arises from various factors, including device non-linearities and thermal noise. Substrate loss currents contribute to this problem by introducing unwanted non-linearities into the amplification process.

Another source of distortion is the Early effect, which causes variations in the transistor's gain by changing the effective width of the base region with varying collector voltage. Although differential amplifiers and cascode stages have been employed to mitigate these effects and improve linearity, these approaches often increase circuit complexity and may not fully address the underlying issues caused by substrate loss currents.

Conventional solutions do not sufficiently suppress substrate loss currents without adding significant complexity or cost to the amplifier design. This ongoing challenge necessitates an innovative approach to semiconductor device and amplifier circuit design, aiming to enhance audio fidelity while minimizing distortion and efficiently managing substrate loss currents.

### BRIEF SUMMARY OF THE INVENTION

Embodiments described herein provide an amplifier circuit designed to minimize distortion in audio signals through the strategic use of BJTs, some of which incorporate substrate loss pickup elements for improved performance. According to some embodiments, a semiconductor amplifier circuit includes a semiconductor device designed to enhance audio signal fidelity by addressing distortion caused by substrate loss currents. This approach integrates semiconductor devices with and without substrate loss pickup elements within a comprehensive circuit framework, aiming to deliver high-quality, undistorted audio signals across various applications, particularly in high-fidelity audio systems.

In some embodiments, the semiconductor amplifier circuit comprises a differential amplifier, a current mirror, and a plurality of cascode stages. The differential amplifier and current mirror can be configured with a first plurality of semiconductor devices for initial signal amplification. These devices are selected for their efficiency in signal amplification where the impact of substrate loss may be minimal, ensuring the integrity of the initial amplification process. The cascode stages, complementing the differential amplifier and current mirror, include one or more semiconductor devices each equipped with a substrate loss pickup element. This configuration can be specifically designed for signal amplification and substrate loss current mitigation, highlighting the innovative approach to maintaining signal linearity and reducing distortion induced by substrate loss currents.

In other embodiments, the semiconductor amplifier circuit comprises two current mirrors, and a plurality of cascode stages. The current mirrors can be configured with a first plurality of semiconductor devices for initial signal amplification. These devices are selected for their efficiency in signal amplification where the impact of substrate loss may be minimal, ensuring the integrity of the initial amplification process. The cascode stages, complementing the current mirrors, include one or more semiconductor devices each equipped with a substrate loss pickup element. This configuration can be specifically designed for signal amplification and substrate loss current mitigation, highlighting the innovative approach to maintaining signal linearity and reducing distortion induced by substrate loss currents.

In other embodiments, the semiconductor amplifier circuit comprises two Wilson current mirrors. The Wilson current mirrors can be configured with a first plurality of semiconductor devices for initial signal amplification. These devices are selected for their efficiency in signal amplification where the impact of substrate loss may be minimal, ensuring the integrity of the initial amplification process. The Wilson current mirrors include one or more semiconductor devices each equipped with a substrate loss pickup element. This configuration can be specifically designed for signal amplification and substrate loss current mitigation, highlighting the innovative approach to maintaining signal linearity and reducing distortion induced by substrate loss currents.

Further embodiments incorporate one or more bias networks applied to any or all of the differential amplifier, current mirror and the cascode stages. These bias networks are instrumental in setting operating points that are conducive to linear amplification. By carefully adjusting the bias voltages, the embodiments ensure that the semiconductor devices operate within optimal parameters, thus maximizing signal integrity across the audio frequency spectrum. Additionally, one or more input terminals can be provided for supplying the input signal, as either a single-ended or differential voltage or current to the device, and an output terminal can be provided for delivering the amplified audio signal, ensuring that the end output can be performed with minimal distortion.

In some embodiments, the cascode stage specifically includes one or more PNP (or alternatively NPN) transistors, each integrated with a substrate loss pickup element. This integration provides an advantage for enhancing signal linearity by effectively mitigating substrate loss-induced distortion. The substrate loss pickup element's role in these semiconductor devices is to capture and reroute substrate loss currents, thereby preserving the amplified signal's integrity.

Moreover, embodiments of the semiconductor device for an audio amplification circuit feature an emitter region, a base region, and a collector region, along with a strategically positioned substrate loss pickup element. This element can be located proximate to the base region to capture uncollected charge carriers, which significantly reduces distortion in the amplified audio signal. Isolation regions are also included to electrically isolate the semiconductor device from adjacent devices on the semiconductor substrate, further mitigating substrate loss currents and electrical crosstalk that can degrade signal quality.

In some embodiments, the semiconductor devices without a substrate loss pickup element are configured for use in parts of the circuit where the impact of substrate loss may be negligible. This selective integration of devices with and without substrate loss pickup elements underscores an improved approach to circuit design, efficiently addressing distortion without unnecessarily complicating the circuit's overall architecture.

Additionally, embodiments may include a power supply connection featuring a low dropout regulator. This regulator ensures a stable voltage supply to the semiconductor devices, thereby guaranteeing consistent operation and further contributing to the reduction of signal distortion.

In some embodiments, the semiconductor device comprises materials characterized by high electron mobility for the substrate loss pickup element. This choice of materials facilitates the effective capture and redirection of substrate loss charge carriers for minimizing substrate loss-induced distortion and ensuring the delivery of clear, high-fidelity audio signals.

The semiconductor device can be selected for integration into high-fidelity audio applications where signal integrity and minimal distortion are paramount. This semiconductor device can include a configuration of the emitter, base, and collector regions, alongside the inclusion of the substrate loss pickup element, to meet the rigorous demands of high-quality audio reproduction.

Embodiments disclosed herein provide a semiconductor amplifier circuit and a semiconductor device that adeptly address the challenges of substrate loss currents and signal distortion in audio amplification. Through innovative circuit design and strategic integration of substrate loss pickup elements, these embodiments ensure that audio signals are amplified with high fidelity, offering enhanced audio quality for a wide range of applications.

### BRIEF DESCRIPTION OF THE DRAWINGS/FIGURES

FIG. 1A is a plan view of a semiconductor device layout for a BJT.

FIG. 1B is a cross-sectional view of the semiconductor device in FIG. 1A, depicting the internal structure of a BJT

FIG. 2A presents a plan view of a semiconductor device, specifically a BJT configured for reducing substrate loss current to minimize distortion in output stages, according to some embodiments.

FIG. 2B illustrates a cross-sectional view of the semiconductor structure for a BJT for reducing distortion within output stages by managing substrate loss paths, according to some embodiments.

FIG. 3A is a schematic of a semiconductor device configured as a differential amplifier and current mirror, employing BJTs for signal amplification.

FIG. 3B is a schematic of a semiconductor device configured as two current mirrors, employing BJTs for signal amplification.

FIG. 4A is a schematic of a semiconductor device circuit configured as a differential amplifier and current mirror with a cascode stage, illustrating a substrate loss path.

FIG. 4B is a schematic of a semiconductor device circuit configured as two current mirrors with a cascode stage, illustrating a substrate loss path.

FIG. 5A is a schematic of a semiconductor device circuit configured as a differential amplifier and current mirror with a cascode stage integrating a substrate loss pickup element within certain BJT structures to enhance the circuit's signal distortion mitigation, according to some embodiments.

FIG. 5B is a schematic of a semiconductor device circuit configured as two current mirrors with a cascode stage integrating a substrate loss pickup element within certain BJT structures to enhance the circuit's signal distortion mitigation, according to some embodiments.

FIG. 6 is a schematic of a semiconductor circuit for reducing distortion in BJT output stages employing two Wilson current mirrors and incorporating semiconductor devices with substrate loss pickup elements, according to some embodiments.

### DETAILED DESCRIPTION OF THE INVENTION

Embodiments may be implemented using integrated or discrete semiconductors, or any combination thereof. Individual transistors may be implemented as pluralities of transistors connected in combination.

It should be understood that the operations shown in the exemplary methods are not exhaustive and that other operations can be performed as well before, after, or between any of the illustrated operations. In some embodiments of the present disclosure, the operations can be performed in a different order and/or vary.

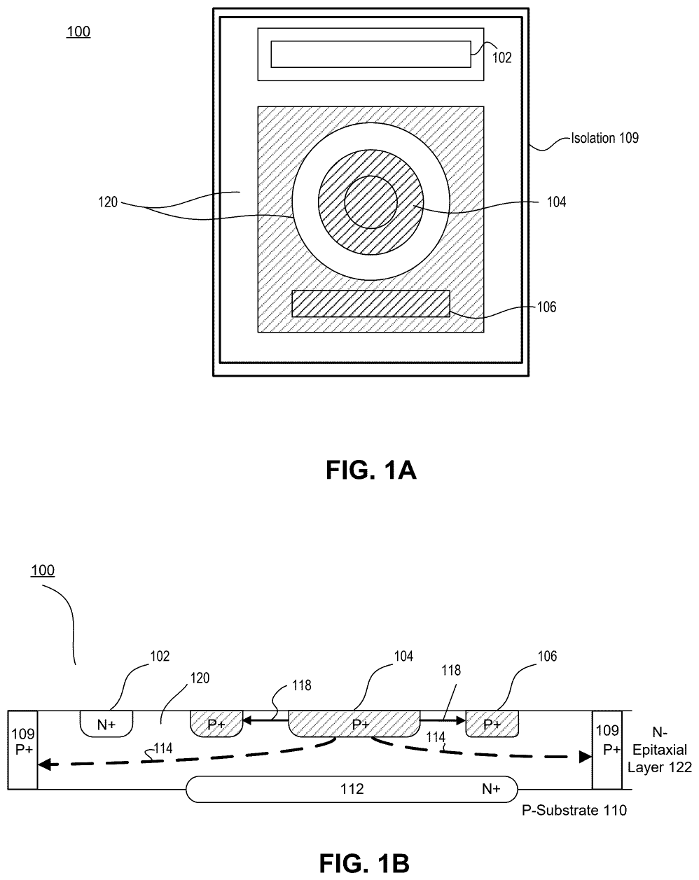

FIG. 1A illustrates a plan view of a semiconductor device 100 layout for a BJT, which can amplify audio signals. Semiconductor device 100 includes a base contact and highly doped base contact region 102, a lightly doped base region 120, an emitter contact and region 104, and a collector contact and region 106. Semiconductor device 100 includes a centrally located emitter region 104 encircled by a base region 120 and an outer collector region 106. Semiconductor device 100 can facilitate charge carrier movement, optimizing the BJT's performance. Base contact and regions 102 and 120 are be provided as N doped layers, while emitter region 104 and collector region 106 can be provided as P doped layers, forming a PNP transistor. Alternatively, NPN transistors are known.

FIG. 1B depicts a cross-sectional view of the semiconductor device 100, for example, for use in a circuit for signal amplification. As shown in FIG. 1A above, FIG. 1B depicts emitter region 104 as a heavily doped area designed to inject charge carriers efficiently into base region 120. The emitter region's high doping concentration can facilitate injection efficiency for the BJT's amplification process. Base regions 102 and 120 can be doped to optimize the base's role in controlling the flow of charge carriers (e.g., current 118) from the emitter to the collector. The precise width of the base can be essential for maintaining efficient transistor operation, with too wide a base leading to increased recombination losses and too narrow a base potentially causing device breakdown.

FIG. 1B clarifies the layered structure and spatial relationships among the base regions 102 and 120, emitter region 104, and collector region 106 within the device, ensuring a precise understanding of its operational dynamics.

In this arrangement, known as a lateral transistor, the base region 120 can be positioned adjacent to the emitter 104, with the collector 106 located on the opposite side of the emitter. This configuration enables charge carrier injection and collection allowing the transistor to be capable of performing signal amplification, and can facilitate the efficient transfer and control of charge carriers essential for amplification. Base region 120 can function as a control point, allowing a small base current to modulate a larger current 118 flowing from the emitter to the collector. Its design parameters, such as width and doping concentration, can be optimized for effective carrier flow and control over the BJT's active operations.

Emitter 104 can be designed to inject charge carriers, electrons or holes, where they are then collected as current 118 by the collector 106. The spatial arrangement ensures minimal carrier recombination and maximizes the efficiency of current amplification. These regions can be refined by doping level, geometric design and/or other attributes critical for the transistor's gain and linearity.

Collector region 106 collects charge carriers based on the base, which manages the voltage drop across the transistor, and features a lightly doped material to effectively handle power dissipation.

Semiconductor device 100 can include P+ isolation regions 109 and N+ buried layer 112, beneath N-epitaxial layer 122, to enhance performance by providing a low-resistance path for current flow and minimizing parasitic capacitances and substrate loss currents. N+ buried layer 112, for example, can be a highly doped N-type semiconductor layer positioned beneath the epitaxial layer (N-layer) in silicon technology. N+ buried layer 112 provides a low-resistance path for the flow of current between the collector region and the external circuit, enhancing the BJT's efficiency and performance. By offering a low-resistance path, it can enable higher operating frequencies, making the BJT suitable for RF and high-speed applications. The N+ buried layer can also help isolate components from the substrate, minimizing parasitic capacitances and substrate loss currents, maintaining the integrity of the signals being processed. The N+ buried layer, situated beneath the emitter and the base, provides a low-resistance path for electrons, improving the transistor's efficiency and frequency response. In addition, the isolation region 109 segregates the transistor from adjacent devices, preventing electrical interference and preserving signal integrity.

In a non-limiting example, substrate 110 can be a P-type substrate having an N-epitaxial layer 122 provided to provide a foundation for the BJT structure. The substrate supports the entire structure and influences the electrical properties of the BJT, including breakdown voltage and carrier mobility. This substrate choice can ensure the device operates within desired parameters, highlighting the importance of substrate engineering in semiconductor device design.

Isolation regions 109 can also be provided to electrically isolate the BJT from adjacent devices on the same substrate. This isolation can be critical for preventing crosstalk and operational interference, which can degrade signal quality.

In an example, N+ buried layer 112 can be disposed below epitaxial layer 122, providing a low-resistance path for the collector current and aiding in device isolation. Substrate 110 can be a P-type substrate having a negative voltage (V− ) applied to establish the correct operating conditions for the BJT, emphasizing the importance of substrate choice in device design.

Contacts (not shown in FIG. 1B) can facilitate external electrical connections to the BJT, optimized for low resistance and precision in interfacing with the semiconductor material. These contacts ensure minimal signal loss during transmission.

In semiconductor devices, particularly BJTs such as semiconductor device 100 and used in audio amplification circuits, substrate loss currents present a significant challenge, degrading signal integrity and leading to distortion. As shown, substrate substrate loss paths 114 illustrate some routes through which unintended currents can flow outside the desired path from emitter to collector, for example, due to minority carrier injection and diffusion in the substrate. These paths not only reduce the efficiency of the transistor's amplification process but can also potentially introduce noise and distortion, compromising the fidelity of the amplified audio signal.

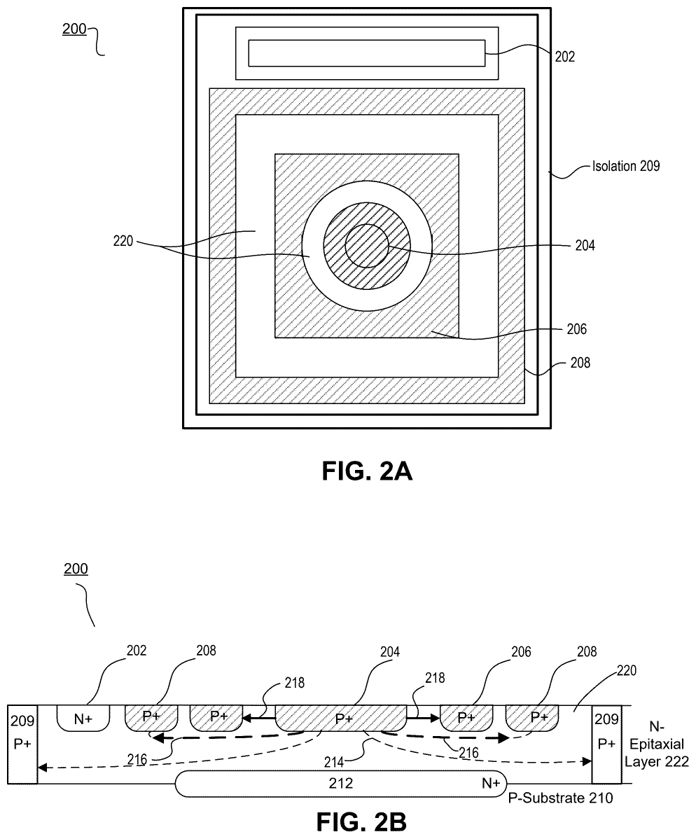

FIG. 2A provides a novel semiconductor device 200, specifically designed for a BJT to reduce substrate loss current, for example, for minimizing distortion in audio amplification applications. Semiconductor device 200 includes a base contact and highly doped base contact region 202, a base region 220, an emitter contact and region 204, and a collector contact and region 206. Semiconductor device 200 additionally incorporates substrate loss pickup element contact and region 208, positioned to address and mitigate substrate loss currents that can lead to signal distortion.

Collector region 206 and emitter region 204 are optimized for the efficient injection of charge carriers. In some non-limiting examples, the geometric design and doping levels can be optimized to control the flow and recombination of carriers. In some embodiments, base regions 202 and 220 can be provided having a shape and/or doping profile optimized allowing for effective modulation of the current flow 218 from emitter to collector for the BJT's amplification function.

Semiconductor device 200 incorporates isolation regions 209, integral to the semiconductor device's performance. These regions ensure electrical isolation of the BJT from other components on the semiconductor chip, for reducing substrate loss currents from adjacent devices and minimizing the parasitic capacitance that could affect the BJT's frequency response. The inclusion of metal contacts (not shown in FIG. 2B) for the collector, base, emitter, and substrate loss pickup element facilitates external connections to the BJT, ensuring low resistance and precise interfacing with the semiconductor material.

FIG. 2B provides a cross-sectional view of the semiconductor device 200, detailing the internal structure and doping profiles engineered to enhance the BJT's performance in audio applications. As shown, base regions 202 and 220, emitter region 204, collector region 206, and substrate loss pickup element 208 are provided, including exemplary doping concentrations and configurations.

Base region 202 is depicted having an N+ doping profile, for efficient charge carrier modulation and control. Base region 220 has an N doping profile, and controls the BJT's amplification of signals by modulating the flow of carriers (e.g., current 218) from the emitter to the collector. Emitter region 204 and collector region 206, depicted for example as heavily doped P+ regions, can be optimized for their roles in charge carrier injection and collection, respectively.

In semiconductor device 200, as in semiconductor device 100 above, substrate loss currents can potentially degrade signal integrity leading to distortion. Substrate loss paths 214 and 216 illustrate routes through which unintended currents can flow outside the desired path due to minority carrier injection and diffusion in the N-epitaxial layer 220. Substrate loss path 214 leads to the P-type substrate 210, reducing the efficiency of the transistor's amplification process and potentially introducing noise and distortion, compromising the fidelity of the amplified audio signal.

However, to counteract this phenomenon, the semiconductor device 200 incorporates a substrate loss pickup element 208 configured to intercept and mitigate substrate loss currents, particularly addressing path 216 depicted in FIG. 2B. This element effectively captures stray charge carriers before they contribute to substrate loss, rerouting them away from the active transistor regions. Semiconductor device 200 can thereby implement substrate loss pickup element 208 to maintain the purity of the amplified signal, ensuring high-fidelity audio reproduction with minimized distortion. The remaining substrate loss path 214 is substantially reduced in magnitude compared to substrate loss path 114 of FIG. 1B. Substrate loss pickup element 208 is depicted as having an exemplary P+ doping profile.

As illustrated in FIGS. 2A and 2B, semiconductor device 200 can include substrate loss pickup element 208 as a specialized region for addressing substrate loss current issues inherent in high-performance BJTs. This element improves the device's ability to deliver clean, undistorted audio signals by capturing and neutralizing substrate loss currents before they can impact the amplifier's operation. Substrate loss pickup element 208 may be advantageously connected to a point with an electrical potential near that of substrate 110 to facilitate its role in intercepting and mitigating substrate loss currents. Additionally, the connection point of substrate loss pickup element 208 may be advantageously chosen within the circuit to minimize or eliminate the distortion caused by substrate loss currents.

For the mitigation of substrate loss currents, selection of materials for substrate loss pickup elements 208 should be based on the objective to effectively capture and redirect substrate loss charge carriers. For example, the substrate loss pickup elements 208 can be fabricated from materials characterized by high electron mobility. This property can enable rapid and efficient transport of electrons, enhancing the device's ability to neutralize substrate loss currents that would otherwise contribute to signal distortion.

Materials such as doped silicon, gallium arsenide (GaAs), or indium phosphide (InP) are considered for the substrate loss pickup elements due to their superior electron mobility compared to conventional silicon. Specifically, silicon doped with elements like phosphorus or arsenic for N-type conductivity, or boron for P-type conductivity, can be tailored to optimize the electron mobility within the substrate loss pickup elements. Alternatively, compound semiconductors like GaAs or InP may be employed for their inherently high electron mobility, offering further improvements in substrate loss current mitigation.

These materials are selected to ensure that the substrate loss pickup elements not only effectively capture and reroute substrate loss currents away from the active regions of the transistor but also contribute to the overall stability and performance of the semiconductor device. The implementation of such materials can enable semiconductor device 200 to substantially address substrate loss currents and signal distortion in audio amplification, for delivering clear, high-fidelity audio signals.

While such materials are suggested, a person having ordinary skill in the art would understand that the choice of materials for the substrate loss pickup elements is guided by the principle of maximizing electron mobility to enhance the device's ability to manage substrate loss currents efficiently. As such, alternative suitable materials may be selected consistent with the design considerations of the disclosed semiconductor devices, with the intent to improve audio signal fidelity through advanced distortion reduction techniques.

Through the structuring of the above regions, semiconductor device 200 exemplifies an approach to BJT design that can be implemented in specific use cases for audio amplification to prioritize signal integrity and to minimize distortion by substrate loss management and optimal carrier flow dynamics. Substrate loss currents in semiconductor devices, particularly in BJTs designed for audio amplification, can significantly impact device performance by introducing unwanted noise and distortion, thus degrading the quality of the output signal. Recognizing this challenge, the invention integrates a substrate loss pickup element 208, specifically designed to address and mitigate substrate loss currents effectively. This element can be positioned within the semiconductor device 200 to intercept substrate loss paths, notably path 216 in FIG. 2B, that would otherwise contribute to signal degradation. The incorporation of this element underscores a targeted approach to preserving signal integrity, ensuring that the amplified audio maintains high fidelity with minimal distortion. Substrate loss pickup element 208 can be specifically engineered to address and shunt undesired substrate loss currents away from the active regions of the transistor. This component enables preservation of the integrity of the amplified signal and minimization distortion.

In some embodiments, semiconductor device 100 and 200 can be provided having silicon substrate and can include field oxide elements, such as epitaxial layers. In some embodiments, N+ buried layers 112 and 212 and P+ regions can be doped with phosphorus or arsenic for N-type conductivity, and boron for P-type conductivity, ensuring precise control over the carrier concentration and mobility. In some embodiments, substrate loss pickup element 208 could be formed from a lightly doped P-type silicon, designed to create a potential barrier that captures and redirects the substrate loss currents.

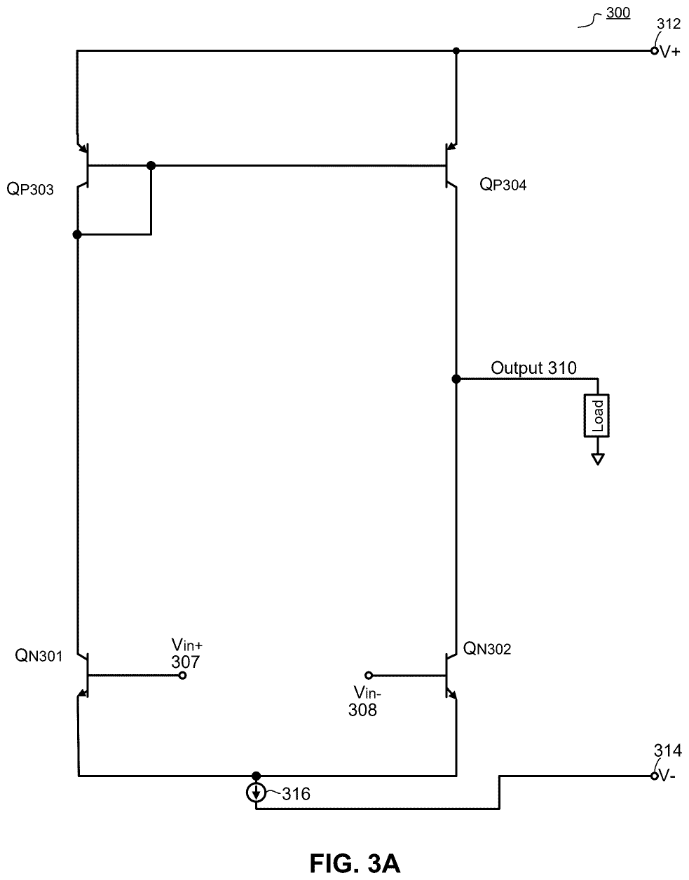

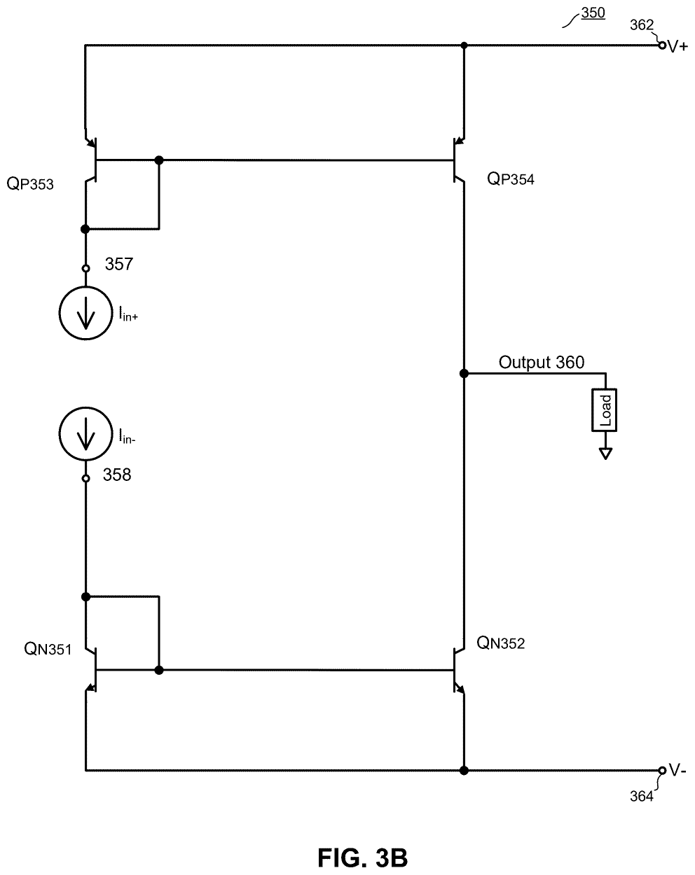

FIG. 3A illustrates a semiconductor device circuit 300 configured as a differential voltage amplifier and current mirror employing BJTs to amplify signals with precision. Semiconductor device circuit 300 circuit comprises NPN transistors QN301 and QN302, coupled with PNP transistors QP303 and QP304, for amplifying differential input voltage signals accurately.

Transistors QN301 and QN302 can create a differential pair, the central component of the amplifier circuit. This pair is configured to amplify a voltage difference between two inputs 307 and 308, represented by voltages Vin+ and Vin− respectively, while suppressing signals common to both. Transistors QP303 and QP304 can be arranged in a current mirror setup. This configuration ensures an identical current through both transistors, thereby providing an output current 310 controlled by the differential pair.

The differential pair and the current mirror, consisting of transistors QN301, QN302, QP303, and QP304, are configured to operate in their active regions, ensuring the output current is responsive to the differential input voltage. The amplified current signal is taken from the output node connecting QP304 and QN302 at output 310. This node delivers the amplified signal, processed by the BJT pair with linearity and minimal influence from variations due to temperature or power supply fluctuations.

Current source 316 provides negative current to the emitters of transistors QN301, QN302. This current source can be constructed by various means well known to those skilled in the art.

The power supply for the circuit is indicated by V+ terminal 312 and V− terminal 314, which supply the essential voltages for BJT operation. These terminals set the voltage levels for the circuit's operation. Proper management of these power supply voltages is required to prevent any current excess that could result in thermal issues or damage to the transistors.

Each transistor in the circuit, comprising an emitter, base, and collector, is fundamental to the BJT's operation. The emitters of QN301 and QN302 are linked via current source 312 to the V− supply 314, which helps stabilize the operating point against fluctuations in temperature and variations in transistor properties. The bases of QN301 and QN302 serve as the input terminals 307 for Vin+ and 308 for Vin− for the differential input voltage signals, marking the start of the signal amplification process.

The emitters of QP303 and QP304 connect to the V+ supply, appropriate to a current mirror configuration. Semiconductor device circuit 300 can incorporate PNP semiconductor device 100 (or a corresponding NPN device) as any or all of transistors QN301, QN302, QP303, and QP304. In the configuration of FIG. 3A, QN301 and QN302 are NPN devices, and QP303 and QP304 are PNP devices.

Thereby, FIG. 3A depicts a semiconductor device with a BJT differential voltage amplifier circuit designed for signal processing applications requiring high linearity and stability.

FIG. 3B illustrates a semiconductor device circuit 350 configured as two current mirrors employing BJTs to amplify signals with precision. Semiconductor device circuit 350 circuit comprises NPN transistors QN351 and QN352, coupled with PNP transistors QP353 and QP354, for amplifying differential current input signals accurately.

Transistors QN351 and QN352 can be arranged in one current mirror setup, and transistors QP353 and QP354 in another. Each configuration ensures an identical current through both corresponding transistors, thereby providing an output current controlled by the difference between the two input currents, represented by signal currents at input terminals 357 (Iin+) and 358 (Iin−), while suppressing signal currents common to both.

The current mirrors, consisting of transistors QN351, QN352, QP353, and QP354, are configured to operate in their active regions, ensuring the output current is responsive to the differential input currents. The amplified current signal is taken from the output node connecting QP354 and QN352 at output 360. This node delivers the amplified signal, processed by the BJT pair with linearity and minimal influence from variations due to temperature or power supply fluctuations.

The power supply for the circuit is indicated by V+ terminal 362 and V− terminal 364, which supply the essential voltages for BJT operation. These terminals set the voltage levels for the circuit's operation. Proper management of these power supply voltages to prevent any current excess that could result in thermal issues or damage to the transistors.

Each transistor in the circuit, comprising an emitter, base, and collector, is fundamental to the BJT's operation. The emitters of QN351 and QN352 are linked to the V− supply, appropriate to a current mirror configuration, which helps stabilize the operating point against fluctuations in temperature and variations in transistor properties. The base-collector junctions of QN351 and QP353 serve as the input terminals for the differential current input signals Iin+ and Iin− at input terminals 357 and 358 respectively, marking the start of the signal amplification process.

The emitters of QP351 and QP352 connect to the V+ supply, appropriate to a current mirror configuration. Semiconductor device circuit 350 incorporates semiconductor device 100 (or a corresponding NPN device) as any or all of transistors QN351, QN352, QP353, and QP354. In the configuration of FIG. 3B, QN351 and QN352 are NPN devices, and QP353 and QP354 are PNP devices.

Thereby, FIG. 3B depicts a semiconductor device with a BJT differential current amplifier circuit designed for signal processing applications requiring high linearity and stability.

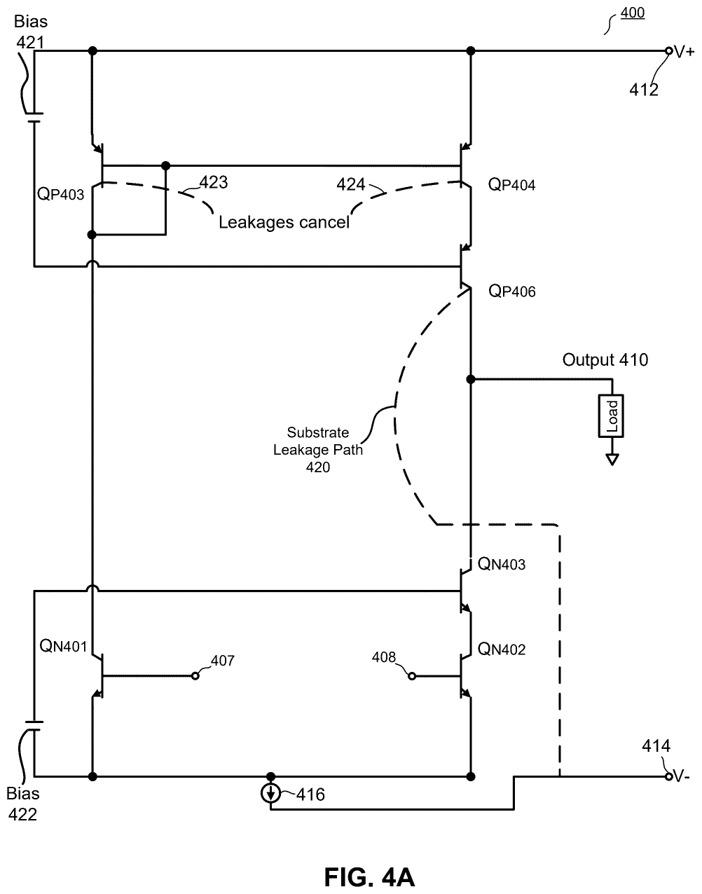

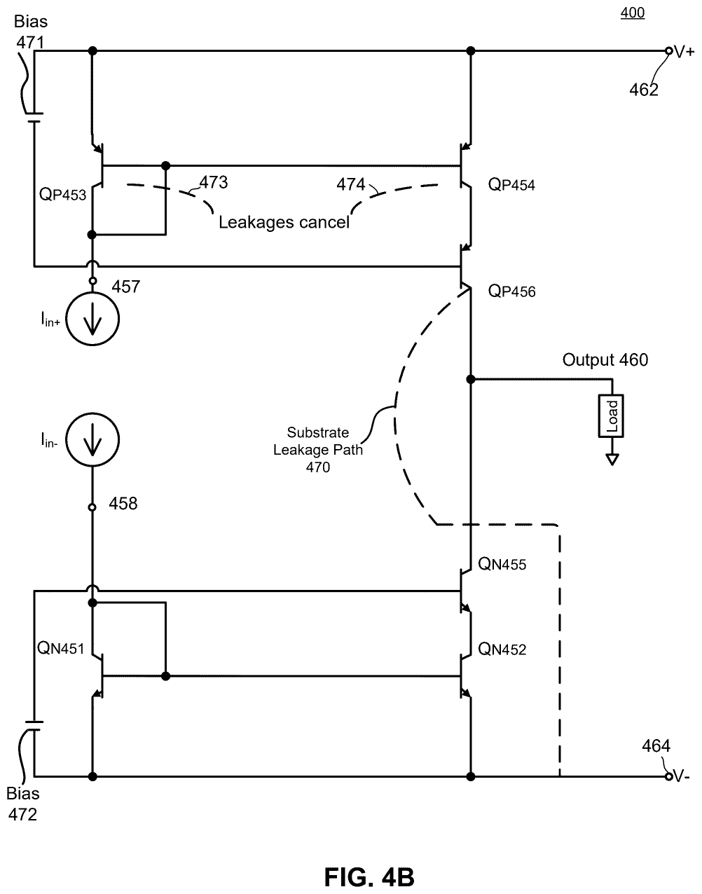

FIG. 4A depicts a semiconductor device circuit 400 based on FIG. 3A additionally depicting aspects associated with substrate loss currents, a significant issue for audio signal integrity. This figure introduces a substrate loss path 420, identifying the flow of unintended substrate loss currents within the semiconductor substrate.

The configuration keeps the differential pair of FIG. 3A with NPN transistors, QN401 and QN402 supplied by current source 416, and pairs this with the current mirror setup of PNP transistors, QP403 and QP404 consistent with FIG. 3A.

FIG. 4A additionally depicts a cascode configuration, using cascode transistors QP406 and QN405. These transistors are important for stabilizing the collector voltages of the differential and current mirror transistors. This stabilization is key to reducing the Early effect's impact on collector current variability, which can cause signal distortion.

The Early effect, a phenomenon where the effective width of the base in a BJT changes with the collector voltage, resulting in a variation of the transistor's current gain, poses a significant challenge in high-fidelity audio amplification.

Bias networks (bias 421 and bias 422) can be applied to set operating points for the cascode transistors, ensuring they operate effectively within their characteristic curves. In a non-limiting example, bias voltages 421 and 422 can be set at 1.2V (or any voltage substantially between approximately 0.65V to approximately 1.3V) to establish optimal operating points for the differential amplifier and current mirror configurations, respectively, ensuring linear operation and maximizing signal integrity across the audio frequency spectrum.

The substrate loss path 420 for cascode transistor QP406, indicated by a dashed line, is shown extending from QP406 to the V− supply. This path represents the unintended substrate loss currents that can compromise the circuit's performance by introducing non-linearities into the signal processing.

Note that substrate loss paths 423 and 424 from current mirror transistors QP403 and QP404 respectively, shown as dashed lines from those transistors to the V− supply, will cancel and thus not produce any non-linearities.

A differential voltage input signal Vin is provided at circuit 400, shown as Vin+ input terminal 407 and Vin− input terminal 408. The output 410 of the circuit is taken from the connection between QP406 and QN405. This point delivers the signal processed by the differential pair and current mirror, further refined by the cascode transistors'voltage stabilization. Power is provided through terminals 412 and 414, for V+ and V− respectively, for the BJTs'operation.

FIG. 4B depicts a semiconductor device circuit 450 based on FIG. 3B, additionally depicting aspects associated with substrate loss currents, a significant issue for audio signal integrity. This figure introduces a substrate loss path 470, identifying the flow of unintended substrate loss currents within the semiconductor substrate.

The configuration keeps the current mirror of FIG. 3B with NPN transistors, QN451 and QN452, and pairs them with the current mirror setup of PNP transistors, QP453 and QP454 consistent with FIG. 3B.

FIG. 4B additionally depicts a cascode configuration, using cascode transistors QP456 and QN455. These transistors are important for stabilizing the collector voltages of the differential and current mirror transistors. This stabilization is key to reducing the Early effect's impact on collector current variability, which can cause signal distortion, as explained above.

Bias networks (bias 471 and bias 472) can be applied to set operating points for the cascode transistors, ensuring they operate effectively within their characteristic curves. In a non-limiting example, bias voltages 471 and 472 can be set at 1.2V (or any voltage substantially between approximately 0.65V to approximately 1.3V) to establish optimal operating points for the differential amplifier and current mirror configurations, respectively, ensuring linear operation and maximizing signal integrity across the audio frequency spectrum.

The substrate loss path 470 for cascode transistor QP406, indicated by a dashed line, is shown extending from QP456 to the V− supply. This path represents the unintended substrate loss currents that can compromise the circuit's performance by introducing non-linearities into the signal processing.

Note that substrate loss paths 473 and 474 from current mirror transistors QP453 and QP454 respectively, shown as dashed lines from those transistors to the V− supply, will cancel and thus not produce any non-linearities.

A differential current input signal Iin is provided at circuit 450, shown as currents at terminals 457 (Iin+) and 458 (Iin−). The output 460 of the circuit is taken from the connection between QP456 and QN455. This point delivers the signal processed by the differential pair and current mirror, further refined by the cascode transistors'voltage stabilization. Power is provided through terminals 462 and 464, for V+ and V− respectively, for the BJTs'operation.

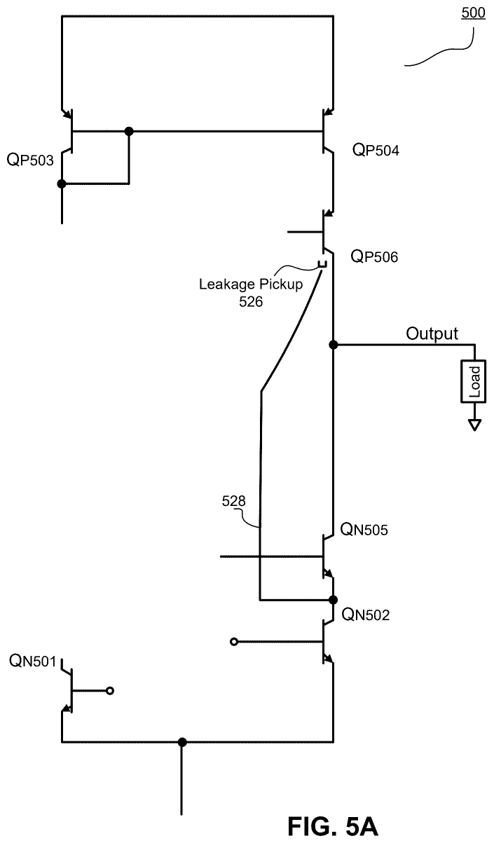

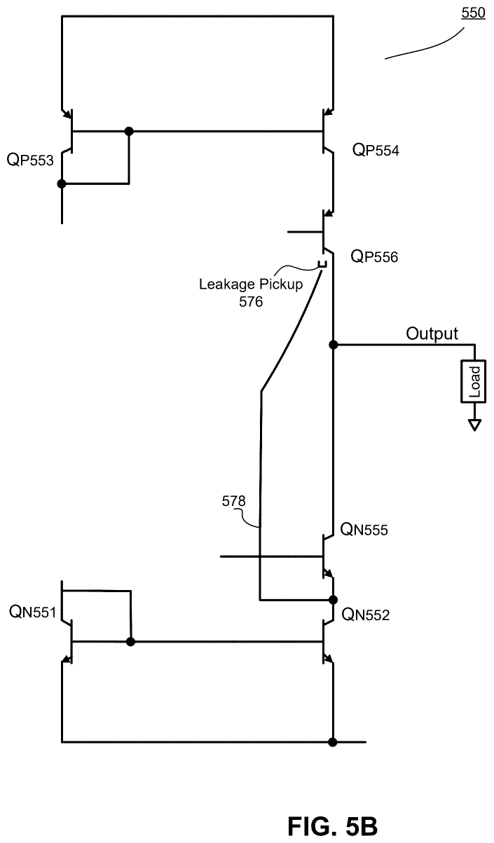

FIG. 5A depicts semiconductor device circuit 500, which modifies semiconductor device circuit 400 by adding a substrate loss pickup feature within the BJT structure to improve upon the design shown in FIG. 4A. This figure introduces as cascode BJT QP506 a semiconductor device 200, equipped with substrate loss pickup 208, designed to capture and mitigate substrate loss currents that might cause distortion, particularly in high-fidelity audio applications.

In some embodiments, QN501, QN502, QP503, QP504 and QN505 can be provided as semiconductor device 100 (or alternative NPN structures). Conversely, transistor QP506 can be a variant of semiconductor device 200, distinctively integrated with substrate loss pickup 208. Positioned in a cascode arrangement, transistors QN505 and QP506 aim to stabilize collector voltages and minimize the Early effect's influence. Such a configuration is essential for preserving the output signal's linearity by ensuring collector-emitter voltage variations do not affect the transistor currents.

In addition to mitigating the Early effect, described above, semiconductor devices in the cascode stage of FIG. 5A can incorporate substrate loss pickup elements, shown in the schematic as substrate loss pickup terminal 526, offering an alternative route for substrate loss currents that the collector of QP506 does not capture. This redirection lessens the impact of these currents on the circuit's functionality. The substrate loss pickup is critical for intercepting currents before they compromise the substrate or other transistor regions, potentially causing output signal non-linearities.

The design of semiconductor device 200, featuring substrate loss pickup 208, is especially beneficial under conditions of higher power levels and voltages where substrate loss issues may be pronounced. This integration allows the device to sustain high performance in challenging conditions, making it suitable for professional audio applications where maintaining signal integrity is desirable. As described above, semiconductor device 200 includes substrate loss pickup elements 208 to ensure this output withstands distortion from substrate loss currents thereby improving audio quality over traditional designs.

Substrate loss pickup terminal 526 is connected via path 528 to the emitter of cascode transistor QN505. This allows the cancellation of any effects of the substrate loss current picked up from QP506. The collector current of QP506 will be lessened by this substrate loss current. By applying the current to the emitter of QN505, the collector current of QN505 will be lessened by the exact same amount, thus canceling any substrate loss current effect, particularly including canceling any distortions otherwise produced thereby.

Power to the BJTs is supplied through V+ and V− similar to what is shown in FIG. 4A, ensuring the transistors from both semiconductor device 100 and semiconductor device 200 operate optimally. Thereby, semiconductor amplifier circuit further by integrating a substrate loss pickup in certain transistors, specifically semiconductor device 200, while keeping standard BJT designs, semiconductor device 100, for the rest of the circuit. This strategic incorporation leverages the substrate loss pickup's benefits in reducing distortion where it is most effective. Consequently, the semiconductor device achieves high-fidelity amplification with reduced distortion, designed for audio applications requiring the utmost signal quality.

FIG. 5A depicts a semiconductor device design by specifically integrating a substrate loss pickup feature within the BJT structure, addressing the shortcomings identified in FIG. 4A. FIG. 5A introduces semiconductor device 200, a particular BJT equipped with substrate loss pickup 208, which is a novel implementation designed to capture and mitigate substrate loss currents that could lead to distortion, especially in high-fidelity audio applications. In some embodiments, the semiconductor device of FIG. 5A can be implemented to minimize distortion specifically where one or more lateral PNP transistors is implemented, i.e., transistors having a p-type layer as an emitter and a collector as shown in FIG. 2B.

Specifically, in the cascode stage of device circuit 500, BJTs with substrate loss pickup elements can be provided to address high-susceptibility areas to substrate loss currents, optimizing the circuit's performance without the need for universal replacement, which maintains cost-effectiveness and circuit simplicity. BJTs with substrate loss pickup elements are selected for integration into the cascode stage based on their ability to significantly reduce substrate loss-induced distortion without adversely affecting the circuit's overall power efficiency or introducing undue complexity.

Transistors QN501 and QN502 function as part of the differential amplifier, and transistors QP503 and QP504 part of the current mirror configurations. These transistors may be embodiments of semiconductor device 100, where substrate loss is not significantly impacting their performance. The differential pair and current mirror effectively cancel out any substrate loss currents, making the addition of substrate loss pickup unnecessary for these components.

NPN cascode transistor QN505 similarly is typically an NPN device, which does not exhibit significant substrate loss current.

In contrast, transistor QP506 is an embodiment of semiconductor device 200, specially designed with substrate loss pickup 208. This transistor is placed in a cascode configuration to stabilize the collector voltages and to negate the influence of the Early effect. The cascode transistor maintains linearity of the output signal by preventing variations in collector-emitter voltages from affecting the transistor currents.

The inclusion of substrate loss pickup 208 in semiconductor device 200 provides a significant advantage, functioning as a pathway for substrate loss currents that are not collected by the collector to be rerouted, thereby reducing their influence on the circuit's operation. The substrate loss pickup ensures that these currents are intercepted and do not reach the substrate or affect other regions of the transistor, which could introduce non-linearities in the output signal. By returning the substrate loss current collected by pickup 208 through terminal 526, and routing it via path 528 to the emitter of QN505, the effect of this substrate loss current is canceled, and thus no non-linearities are produced.

Semiconductor device 200 having substrate loss pickup 208 is particularly advantageous in applications where the BJT is subjected to higher power levels and voltages, which can exacerbate substrate loss issues. By integrating the substrate loss pickup into the BJT structure, the device can maintain high performance even under demanding conditions, making it well-suited for professional audio applications where signal integrity is essential. Implementing semiconductor device 200 ensures that the output is more robust against distortion caused by substrate loss currents, offering enhanced audio quality compared to traditional designs.

The power supply connections, V+ and V−, provide necessary voltage levels for the operation of the BJTs. The voltage powers the transistors of both semiconductor device 100 and semiconductor device 200, to operate within their optimal parameters.

Thereby, FIG. 5A depicts a semiconductor device that builds upon the established BJT amplifier circuit by selectively incorporating a substrate loss pickup in specific transistors, namely semiconductor device 200 for QP506, while maintaining semiconductor device 100 for other parts of the circuit. This selective integration highlights the design's efficiency, utilizing the substrate loss pickup only where it provides a tangible benefit in reducing distortion. The result is a semiconductor device that delivers high-fidelity amplification with minimized distortion, configured for audio applications demanding the highest quality signal reproduction.

FIG. 5B depicts semiconductor device circuit 550, which modifies semiconductor device circuit 450 by adding a substrate loss pickup feature within the BJT structure to improve upon the design shown in FIG. 4B. This figure introduces as cascode BJT QP556 a semiconductor device 200, equipped with substrate loss pickup 208, designed to capture and mitigate substrate substrate loss currents that might cause distortion, particularly in high-fidelity audio applications.

In some embodiments, QN551, QN552, QP553, QP554 and QN555 can be provided as semiconductor device 100 (or alternative NPN structures). Conversely, transistor QP556 can be a variant of semiconductor device 200, distinctively integrated with substrate loss pickup 208. Positioned in a cascode arrangement, transistors QN555 and QP556 aim to stabilize collector voltages and minimize the Early effect's influence. Such a configuration is essential for preserving the output signal's linearity by ensuring collector-emitter voltage variations do not affect the transistor currents.

In addition to mitigating the Early effect, described above, semiconductor devices in the cascode stage of FIG. 5B can incorporate substrate loss pickup elements, shown in the schematic as substrate loss pickup terminal 576, offering an alternative route for substrate loss currents that the collector of QP556 does not capture. This redirection lessens the impact of these currents on the circuit's functionality. The substrate loss pickup is critical for intercepting currents before they compromise the substrate or other transistor regions, potentially causing output signal non-linearities.

The design of semiconductor device 200, featuring substrate loss pickup 208, is especially beneficial under conditions of higher power levels and voltages where substrate loss issues may be pronounced. This integration allows the device to sustain high performance in challenging conditions, making it suitable for professional audio applications where maintaining signal integrity is desirable. As described above, semiconductor device 200 includes substrate loss pickup elements 208 to ensure this output withstands distortion from substrate loss currents thereby improving audio quality over traditional designs.

Substrate loss pickup terminal 576 is connected via path 578 to the emitter of cascode transistor QN555. This allows the cancellation of any effects of the substrate loss current picked up from QP556. The collector current of QP556 will be lessened by this substrate loss current. By applying the current to the emitter of QN555, the collector current of QN555 will be lessened by the exact same amount, thus canceling any substrate loss current effect, particularly including any distortions otherwise produced thereby.

The operation of circuit 550 is substantially analogous to that of circuit 500 with respect to the benefit of the use of semiconductor device 200 including substrate loss pickup element 208, and routing substrate loss current from terminal 576 via path 578.

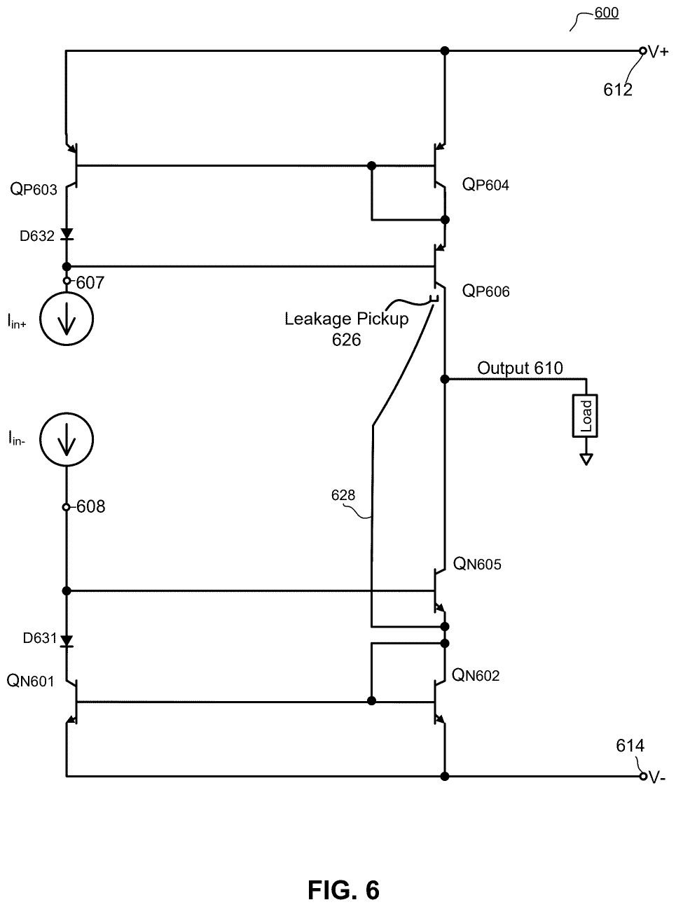

FIG. 6 is a schematic of semiconductor circuit 600 which integrates enhancements into the semiconductor device, specifically targeting distortion reduction in BJT output stages. This configuration introduces semiconductor device 200, equipped with a substrate loss pickup element 626, implemented in QP606, to mitigate the effects of substrate loss currents detrimental to audio signal quality. In some embodiments, semiconductor circuit 600 can be implemented to minimize distortion specifically in circuits comprising lateral PNP transistors, i.e., transistors having a p-type layer as an emitter and a collector.

Semiconductor circuit 600 accepts a differential input current via positive current terminal 607 and negative current input terminal 608, accepting currents Iin+and Iin-respectively.

The circuit utilizes semiconductor devices 100, represented by QN601, QN602, QP603, QP604 and QN605, for roles where substrate loss impacts are minimal. These devices, forming Wilson current mirror configurations, provide essential amplification functionality without necessitating additional substrate loss current management.

Conversely, QP606 (which can be an embodiment of semiconductor device 200, for example) with substrate loss pickup 626, is strategically deployed to address areas susceptible to substrate loss currents. This targeted application underscores the device's design focus on preserving signal integrity, particularly in scenarios prone to increasing substrate loss effects.

One skilled in the art will recognize that the output transistor of a Wilson current mirror, such as QP606 and QN605, is a special case of a cascode transistor whose base bias is provided by other existing elements of the Wilson current mirror, rather than an explicit bias voltage source.

The incorporation of substrate loss pickup 208 in semiconductor device 200 creates a designated path for substrate loss currents, preventing them from compromising circuit performance. This mechanism is pivotal in maintaining the authenticity of the amplified signal, reinforcing the device's applicability in high-fidelity audio settings.

The substrate loss pickup element functions by providing a path for substrate loss currents that bypasses the active regions of the transistor, effectively neutralizing potential sources of distortion. The output signal 610 is available at the node between QN605 and QP606, where enhancements via semiconductor device 200 contribute to reduced distortion, improving audio quality relative to conventional or unmodified BJT designs. By routing the substrate loss current at terminal 626 through path 628 to the emitter of QN605, the effect of the substrate loss current on the output current is canceled, eliminating any distortion caused by the substrate loss current.

Power for the circuit is supplied through V+ terminal 612 and V− terminal 614, essential for the BJTs'operation. The regulation of these power sources facilitates the circuit's consistent functionality.

The deployment of semiconductor device 200, particularly in transistor QP606, directly addresses substrate loss current challenges, optimizing the circuit for superior audio performance. This deliberate design choice not only tackles a key issue in BJT design but also ensures the output 604 signal upholds high fidelity, suitable for professional audio applications.

The mixed transistor configuration, utilizing both conventional BJTs and novel BJTs having substrate loss pickup elements, presents an improved approach to amplifier design, balancing cost, complexity, and performance. This strategy is particularly beneficial in audio amplification circuits where varying stages of signal processing demand different transistor characteristics.

For instance, in the initial stages of amplification, where the signal strength is relatively low, and the susceptibility to noise and distortion is high, conventional BJTs can be employed for superior noise performance and gain characteristics. These stages benefit from the high linearity and low noise figures of standard BJTs, ensuring that the weak audio signals are amplified with minimal addition of noise or distortion.

Conversely, in later stages of amplification, particularly at output stages where the signal has been sufficiently amplified and the circuit is prone to substrate loss currents, BJTs with integrated substrate loss pickup elements can be implemented. These specially designed transistors are configured for mitigating the adverse effects of substrate loss currents that can introduce non-linearity and distortion into the amplified signal. By capturing and rerouting substrate loss currents away from the transistor's active regions, these devices significantly reduce the potential for distortion, ensuring the amplified signal remains as true to the original as possible.

In a non-limiting example, a high-fidelity audio amplifier may be provided in which the initial gain stage can use conventional BJTs for low-noise amplification. As the signal progresses through the amplifier, it encounters stages that may be susceptible to the effects of power supply variations and thermal changes, which can introduce substrate loss currents. In these stages, BJTs with substrate loss pickup elements are utilized to maintain signal integrity, effectively minimizing distortion that could detract from the audio quality.

Diodes D631 and D632 can be provided to further enhance the circuit's ability to manage the Early effect. These diodes cause the collector voltages of QN601 and QP603 to match those of QN602 and QP604 respectively. Consequently, the collector voltage and Early effect will be identical in each corresponding transistor, and its consequences will cancel.

Diodes D631 and D632 can be implemented as diode connected BJTs. If these BJTs are nominally matched to the corresponding transistors QN505 and QN606, and/or located on the same semiconductor substrate, optimal performance may be achieved.

In some embodiments, the semiconductor amplifier circuit depicted in FIG. 4B and FIG. 5B can include temperature compensation components within the bias networks (bias 471, bias 472, bias 571, bias 572), designed to maintain stable operation across varying temperature conditions. These components (not shown) dynamically adjust biasing, compensating for temperature fluctuations and ensuring consistent performance of the semiconductor devices within the circuit.

According to some embodiments, the circuit is configured to operate within a specific audio frequency range, optimizing it for high-fidelity audio applications. This optimization ensures the circuit effectively minimizes distortion and maintains signal integrity across the audible spectrum, making it suitable for demanding audio applications.

Further, the substrate loss pickup element (substrate loss pickup 626) incorporated into semiconductor device QP606 can be formed from materials specifically selected for high electron mobility. This design choice allows for efficient capture and rerouting of substrate loss currents, significantly contributing to the reduction of distortion in the amplified audio signal.

In some embodiments, feedback mechanisms (not shown) can be incorporated to adjust biasing in real-time based on output signal conditions. This adaptability enhances the circuit's response to signal variations, improving audio signal quality. Additionally, the output 604 can be configured to connect to a analog-to-digital converter (ADC) (not shown), facilitating the integration of the amplifier circuit into digital audio systems and ensuring high-quality audio output.

An impedance matching network (not shown) may also be included between the output 604 and the ADC, optimizing signal transfer and minimizing reflection-induced distortion. This network ensures that the audio signal is transmitted with maximum fidelity, aligning with the requirements of high-end audio applications.

Transistors QP606 and QN605, according to some embodiments, can provide feedback control based on the output signal's amplitude (not shown). This control dynamically adjusts amplification levels to prevent clipping and maintain high audio signal quality, effectively addressing signal variability and distortion.

According to some embodiments, a harmonic distortion filtering component (not shown) can be configured to selectively attenuate frequencies contributing to total harmonic distortion. This component can ensure fidelity of the amplified audio signal, making the circuit particularly suited for applications where minimal distortion is paramount. Through these design considerations and the strategic integration of substrate loss pickup elements, the semiconductor amplifier circuit offers an improved solution for high-fidelity audio amplification, demonstrating a comprehensive approach to minimizing distortion and enhancing signal quality.

Thereby, semiconductor circuit 600 can be configured using semiconductor devices 100 for basic amplification and semiconductor devices 200 for advanced substrate loss control. This dual approach effectively minimizes signal distortion, ensuring premium audio output. The inclusion of semiconductor device 200 with substrate loss pickup 626 signifies a major step forward in BJT design, focusing on distortion reduction. This comprehensive strategy demonstrates a focused effort to enhance audio signal integrity and performance.

It is to be appreciated that the Detailed Description section, and not the Summary and Abstract sections, is intended to be used to interpret the claims. The Summary and Abstract sections may set forth one or more but not all exemplary embodiments of the present invention as contemplated by the inventor(s, and thus, are not intended to limit the present invention and the appended claims in any way.

The present invention has been described above with the aid of functional building blocks illustrating the implementation of specified functions and relationships thereof. The boundaries of these functional building blocks have been arbitrarily defined herein for the convenience of the description. Alternate boundaries can be defined so long as the specified functions and relationships thereof are appropriately performed.

The foregoing description of the specific embodiments will so fully reveal the general nature of the invention that others can, by applying knowledge within the skill of the art, readily modify and/or adapt for various applications such specific embodiments, without undue experimentation, without departing from the general concept of the present invention. Therefore, such adaptations and modifications are intended to be within the meaning and range of equivalents of the disclosed embodiments, based on the teaching and guidance presented herein. It is to be understood that the phraseology or terminology herein is for the purpose of description and not of limitation, such that the terminology or phraseology of the present specification is to be interpreted by the skilled artisan in light of the teachings and guidance.

The breadth and scope of the present invention should not be limited by any of the above-described exemplary embodiments, but should be defined only in accordance with the following claims and their equivalents.

What is claimed is:

1. A semiconductor amplifier circuit comprising:
differential input terminals;
an amplifier comprising a plurality of NPN transistors and a plurality of lateral PNP transistors;
an output terminal;
wherein one or more lateral PNP transistors includes a leakage pickup element connected to another circuit node such that the effect of the leakage current is effectively canceled, thus reducing distortion caused by leakage currents, enhancing audio signal fidelity.

2. The semiconductor amplifier circuit of claim 1, wherein the differential input terminals represent a differential voltage input.

3. The semiconductor amplifier circuit of claim 1, wherein the differential input terminals represent a differential current input.

4. The semiconductor amplifier circuit of claim 2, further comprising a differential amplifier and a current mirror.

5. The semiconductor amplifier circuit of claim 3, further comprising two current mirrors.

6. The semiconductor amplifier circuit of claim 3, further comprising two Wilson current mirrors.

7. The semiconductor amplifier circuit of claim 4, 5, or 6 wherein the lateral PNP with leakage pickup element is a cascode transistor, and the leakage pickup element is connected to the emitter of a cascode NPN transistor.

8. The semiconductor amplifier circuit of claim 6, wherein the lateral PNP with leakage pickup element is the output transistor of a Wilson current mirror, and the leakage pickup element is connected to the emitter of an NPN output transistor of another Wilson current mirror.

9. A method for amplifying audio signals using a semiconductor circuit, the method comprising:
providing a pair of input terminals configured to accept a differential input voltage;
coupling the differential inputs to the bases of an NPN differential transistor pair whose emitters are connected to a current source;
coupling the collector of the positive NPN differential transistor to the input of a current mirror comprising a plurality of lateral PNP transistors;
coupling the output of the current mirror to an output terminal through a lateral PNP cascode transistor including a leakage pickup element;
coupling the collector of the negative NPN differential transistor to an output terminal through an NPN cascode transistor;
coupling the leakage pickup element to the emitter of the NPN cascode transistor, such that the leakage current is effective canceled;
supplying power to the semiconductor circuit through a power supply connection to provide necessary voltage levels for the operation of the semiconductor devices; and
outputting an amplified audio signal through the output terminal, wherein the amplified audio signal exhibits reduced distortion due to the connection of the leakage pickup element.

10. A method for amplifying audio signals using a semiconductor circuit, the method comprising:
providing a pair of input terminals configured to accept a differential input current;
coupling the positive and negative differential current inputs to the input of a current mirror comprising a plurality of lateral PNP transistors and the input of a current mirror comprising a plurality of NPN transistors respectively;
coupling the output of the lateral PNP current mirror to an output terminal through a lateral PNP cascode transistor including a leakage pickup element;
coupling the output of the NPN current mirror to an output terminal through an NPN cascode transistor;
coupling the leakage pickup element to the emitter of the NPN cascode transistor, such that the leakage current is effective canceled;
supplying power to the semiconductor circuit through a power supply connection to provide necessary voltage levels for the operation of the semiconductor devices; and
outputting an amplified audio signal through the output terminal, wherein the amplified audio signal exhibits reduced distortion due to the connection of the leakage pickup element.

11. A method for amplifying audio signals using a semiconductor circuit, the method comprising:
providing a pair of input terminals configured to accept a differential input current;
coupling the positive and negative differential current inputs to the input of a Wilson current mirror comprising a plurality of lateral PNP transistors and the input of a Wilson current mirror comprising a plurality of NPN transistors respectively;
implementing the output transistor of the lateral PNP Wilson current mirror as a lateral PNP transistor including a leakage pickup element;
coupling the leakage pickup element to the emitter of the NPN Wilson current mirror output transistor, such that the leakage current is effective canceled;
supplying power to the semiconductor circuit through a power supply connection to provide necessary voltage levels for the operation of the semiconductor devices; and
outputting an amplified audio signal through the output terminal, wherein the amplified audio signal exhibits reduced distortion due to the connection of the leakage pickup element.
